(19) United States
(12) Patent Application Publication
(10) Pub. No.: US 2013/0271928 A1
(43) Pub. Date: Oct. 17, 2013

(54) CIRCUIT MODULE AND METHOD OF MANUFACTURING THE SAME

(71) Applicant: TAIYO YUDEN CO., LTD., Tokyo (JP)

(72) Inventors: Masaya SHIMAMURA, Takasaki-shi (JP); Eiji MUGIYA, Takasaki-shi (JP)

(73) Assignee: TAIYO YUDEN CO., LTD., Tokyo (JP)

(21) Appl. No.: 13/849,364

(22) Filed: Mar. 22, 2013

(30) Foreign Application Priority Data
Apr. 17, 2012 (JP) 2012-093662

(51) Int. Cl. H05K 9/00; H05K 13/00

(52) U.S. Cl. CPC H05K 9/0084; H05K 13/0046
USPC 361/748; 29/841

(57) ABSTRACT

A circuit module pertaining to an embodiment of the present invention has a board, multiple electronic components, a shield member, sealing layer, and cover layer. The board has a mounting surface that includes a first area and second area in which the multiple electronic components are mounted. The shield member is constituted by conductive material and placed between the first area and second area on the mounting surface. The sealing layer has on its top surface a groove having its bottom face including an upper end face of the shield member, is formed on the mounting surface, and is constituted by an insulator that covers the multiple electronic components. The cover layer is constituted by conductive material and has a first cover part that fills the groove as well as a second cover part that covers the first cover part and sealing layer.

### BACKGROUND

1. Field of the Invention

The present invention relates to a circuit module with electromagnetic shield function, as well as a manufacturing method thereof.

2. Description of the Related Art

Circuit modules comprising multiple electronic components mounted on a board, which are installed in various types of electronic equipment, are known. These circuit modules generally adopt a constitution whereby electromagnetic shield function is provided to prevent electromagnetic waves from leaking to the outside of the module or entering from the outside.

In addition, various ingenious ideas are being proposed to prevent electromagnetic interference between these multiple electronic components, as the types of electronic components mounted in circuit modules become increasingly diverse. For example, Patent Literature 1 describes a circuit module having a top shield layer, side shield plates that surround a module board, and an intermediate shield plate placed inside the module board. This circuit module is manufactured by installing, on a board, side shield plates and an intermediate shield plate that are higher than components to be mounted, and then forming an insulation resin layer to cover the mounted components and shield plates, after which the top face of the insulation resin layer is ground to expose the ends of the shield plates. Then, a top shield layer is formed on the surface of the insulation resin layer in a manner also covering the ends of the shield plates, to manufacture the aforementioned circuit module.

### DESCRIPTION OF THE RELATED ART

### Patent Literature

[Patent Literature 1] Japanese Patent No. 4650244

### SUMMARY

With the circuit module described in Patent Literature 1, however, the top shield layer and each shield plate are connected only at the top face of the insulation resin layer, which leads to a potential risk of damage to these connection parts if thermal stress or other stress is applied to the top face in parallel direction. Such damage would render the electrical continuity between the top shield layer and each shield plate unstable, thus making it impossible to achieve stable shield function.

In addition, the circuit module described in Patent Literature 1 is such that the top face of the insulation resin layer is ground to expose the ends of the shield plates on the top face of the insulation resin layer, in order to connect the top shield layer and shield plates. This makes it necessary for the shield plates to be higher than the components on the module board, which in turn makes it difficult to reduce the thickness of the circuit module.

In light of the aforementioned situation, an object of the present invention is to provide a circuit module that ensures stable shield function and also permits thickness reduction, as well as a manufacturing method of such circuit module.

To achieve the aforementioned object, a circuit module pertaining to an embodiment of the present invention has a board, multiple electronic components, shield member, sealing layer, and cover layer, and includes one or more of the following embodiments in any combination.

The board has a mounting surface that includes a first area and second area.

The multiple electronic components are mounted in the first area and second area, respectively.

The shield member is constituted by a first conductor and is placed between the first area and second area of the mounting surface.

The sealing layer has on its top surface a groove having a bottom face including an upper end face of the shield member, is formed on the mounting surface, and is constituted by an insulator that covers the multiple electronic components.

The cover layer has a first cover part that fills the groove as well as a second cover part that covers the first cover part and sealing layer, and is constituted by a second conductor.

By forming on the sealing layer a cover layer constituted by the second conductor, the first cover part filling the groove and second cover part that covers the first cover part and sealing layer are formed.

To achieve the aforementioned object, the manufacturing method of a circuit module pertaining to an embodiment of the present invention includes a step to mount multiple electronic components in a first area and second area on a mounting surface.

A shield member constituted by a first conductor is placed between the first area and second area on the board.

A sealing layer covering the multiple electronic components and shield member and constituted by an insulator is formed on the board.

A part of the sealing layer is removed from the shield member to form a groove to expose the shield member.

A cover layer constituted by a second conductor is formed on the sealing layer, to form a first cover part that fills the groove, as well as a second cover part that covers the first cover layer and sealing layer.

Any discussion of problems and solutions involved in the related art has been included in this disclosure solely for the purposes of providing a context for the present invention, and should not be taken as an admission that any or all of the discussion were known at the time the invention was made.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

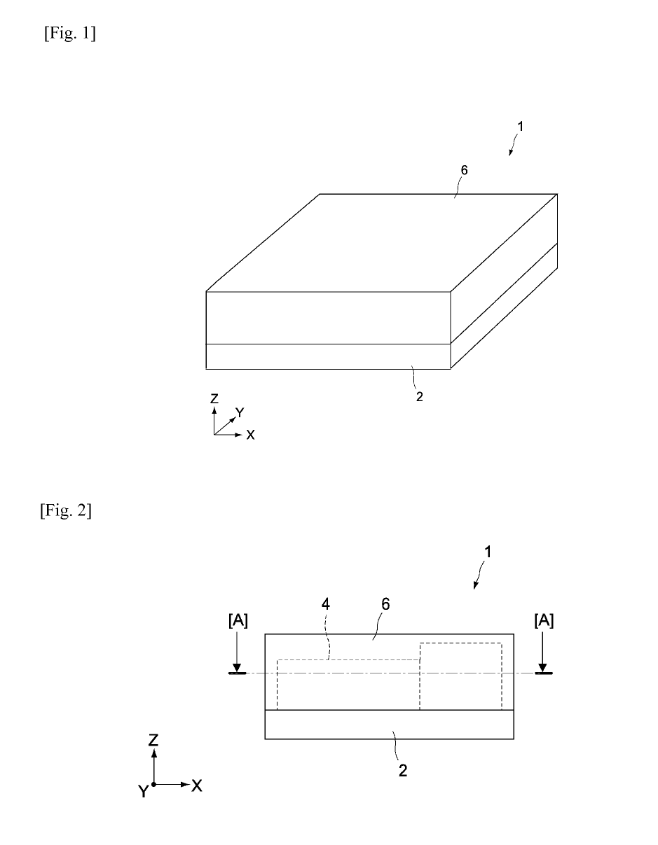

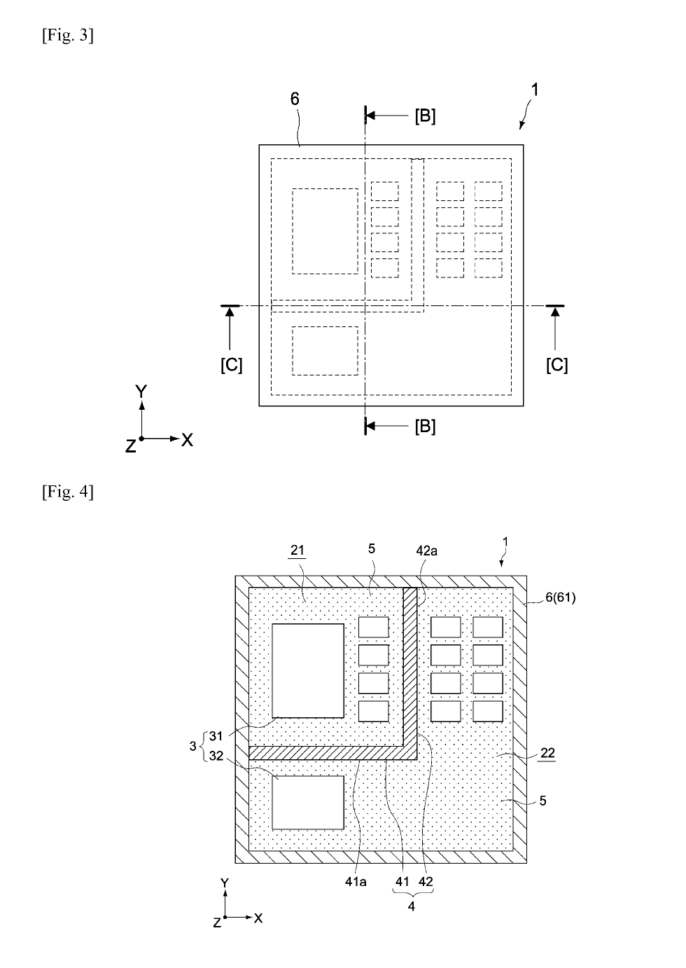

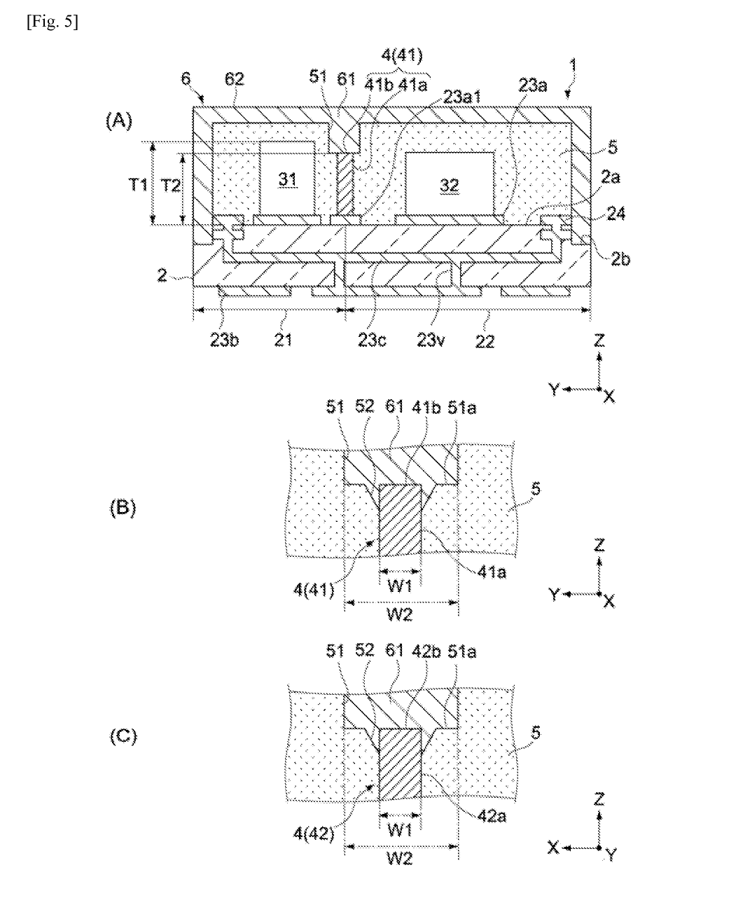

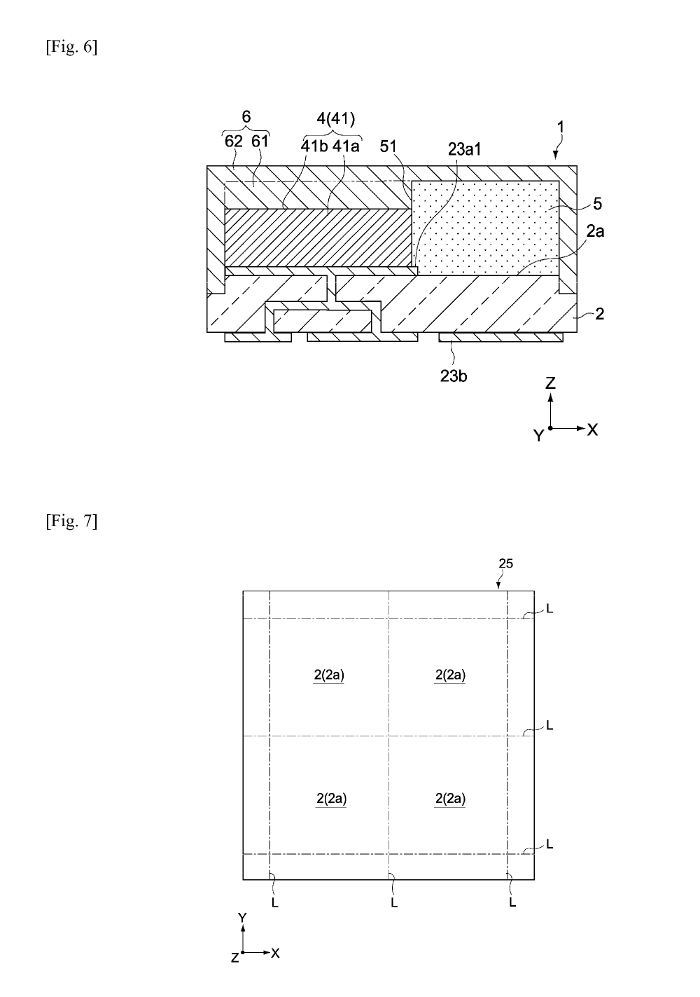

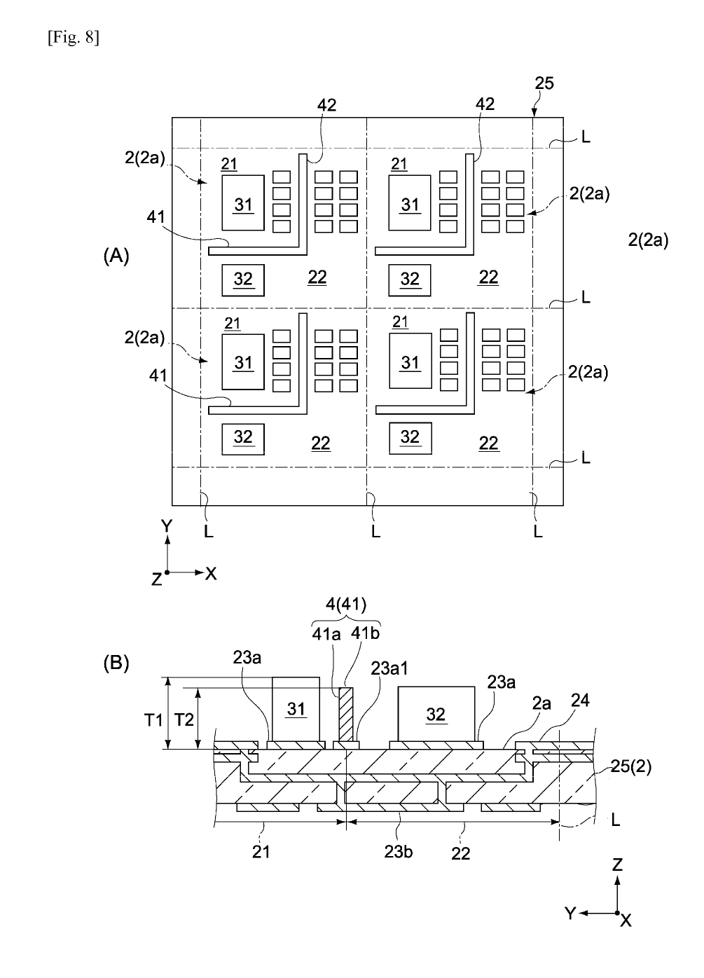

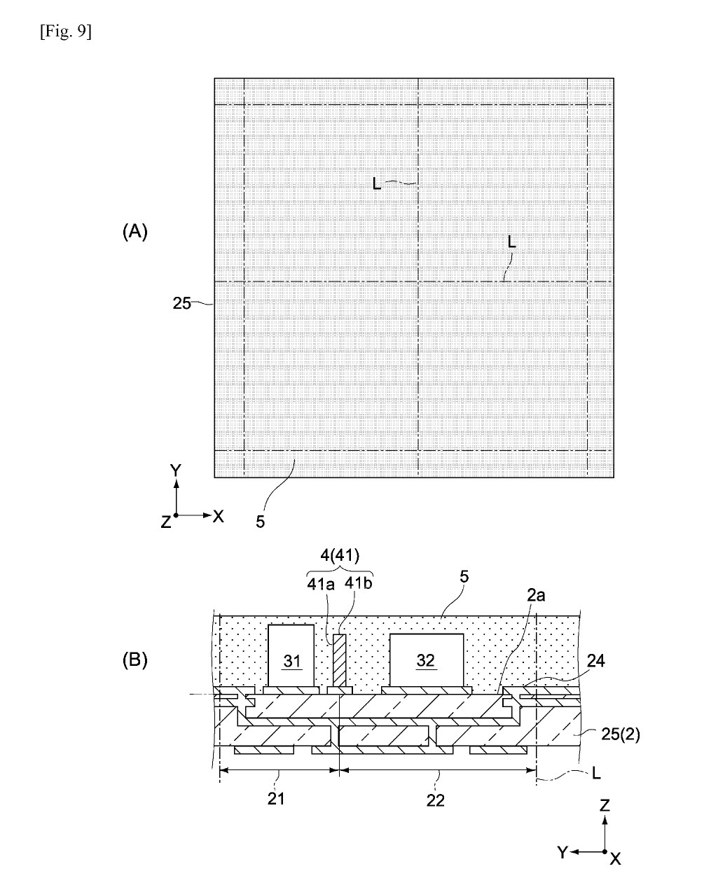

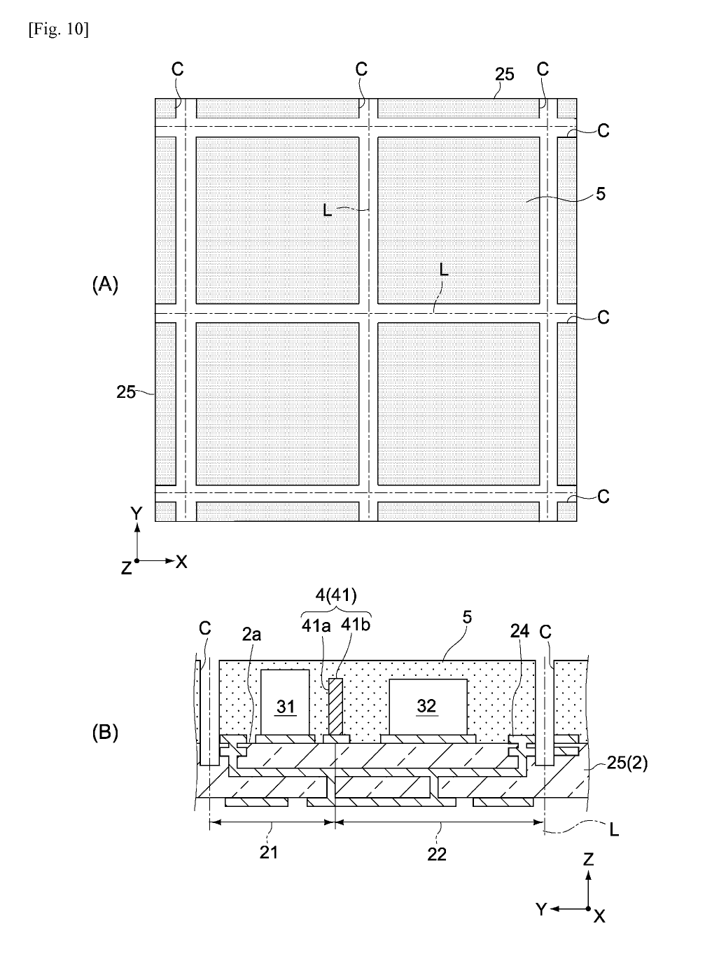

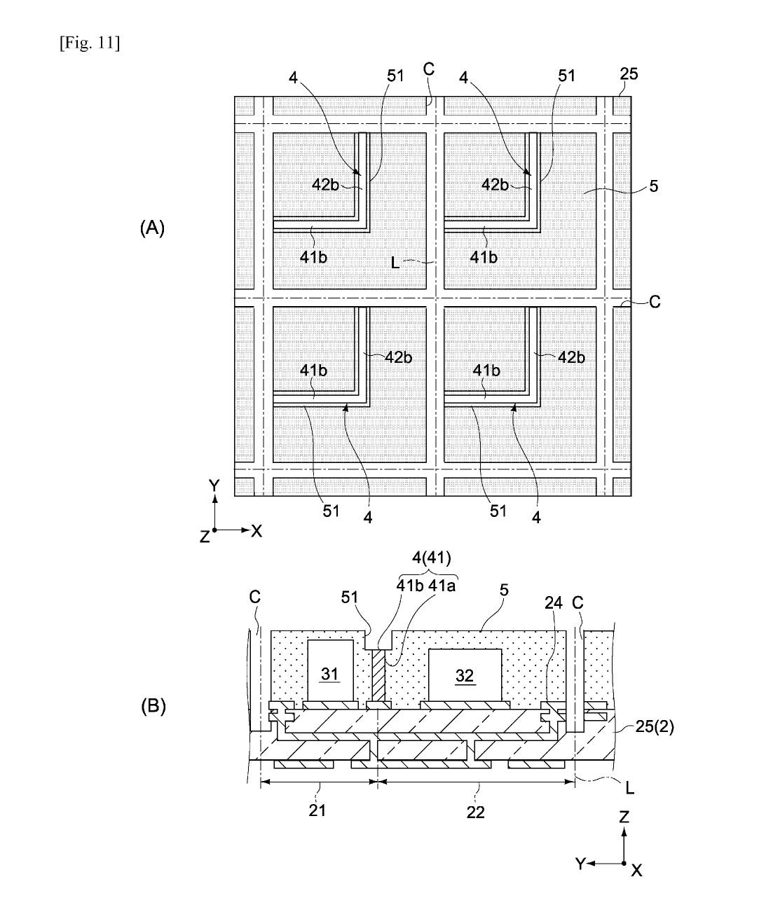

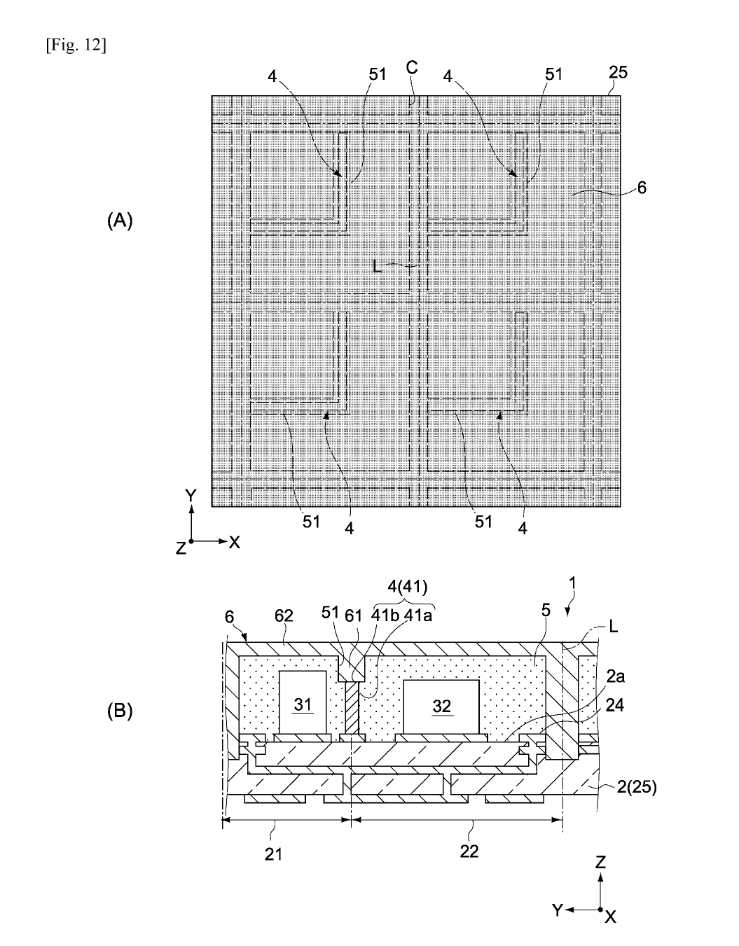

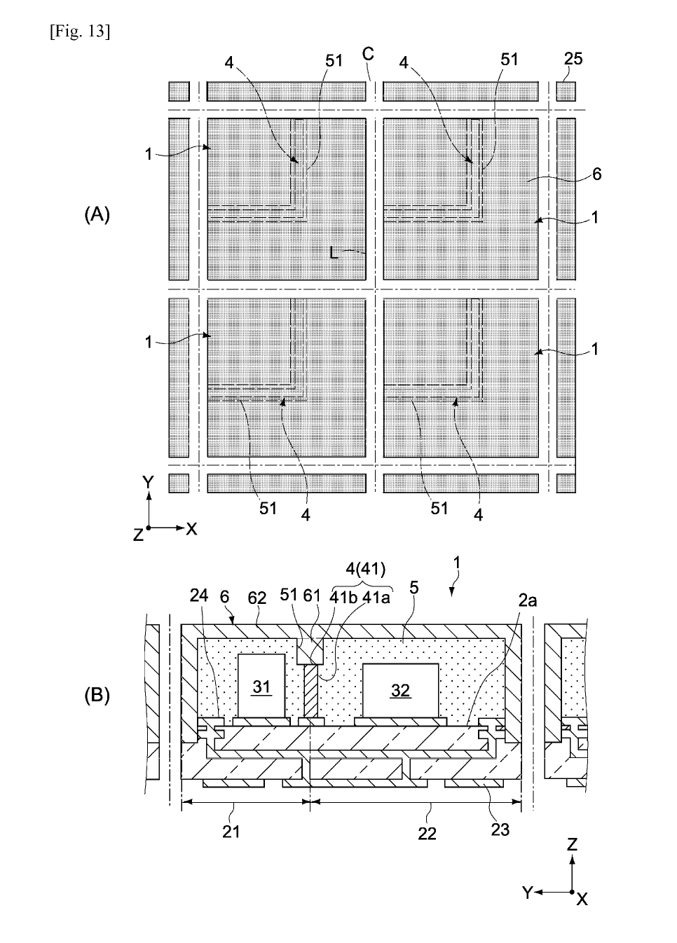

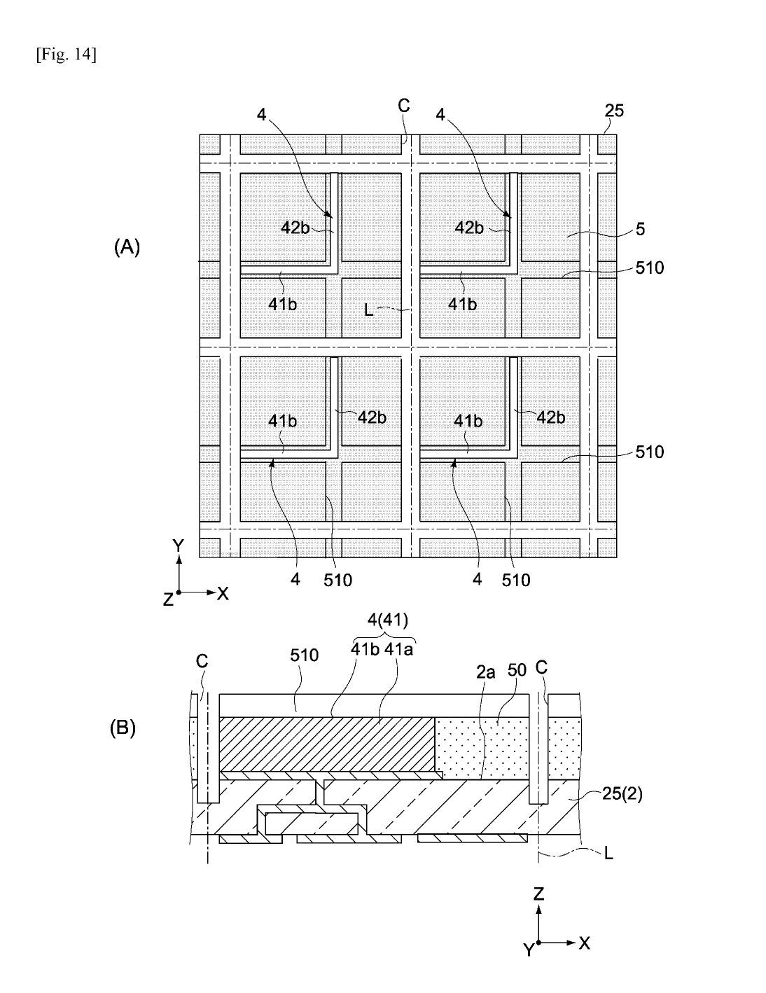

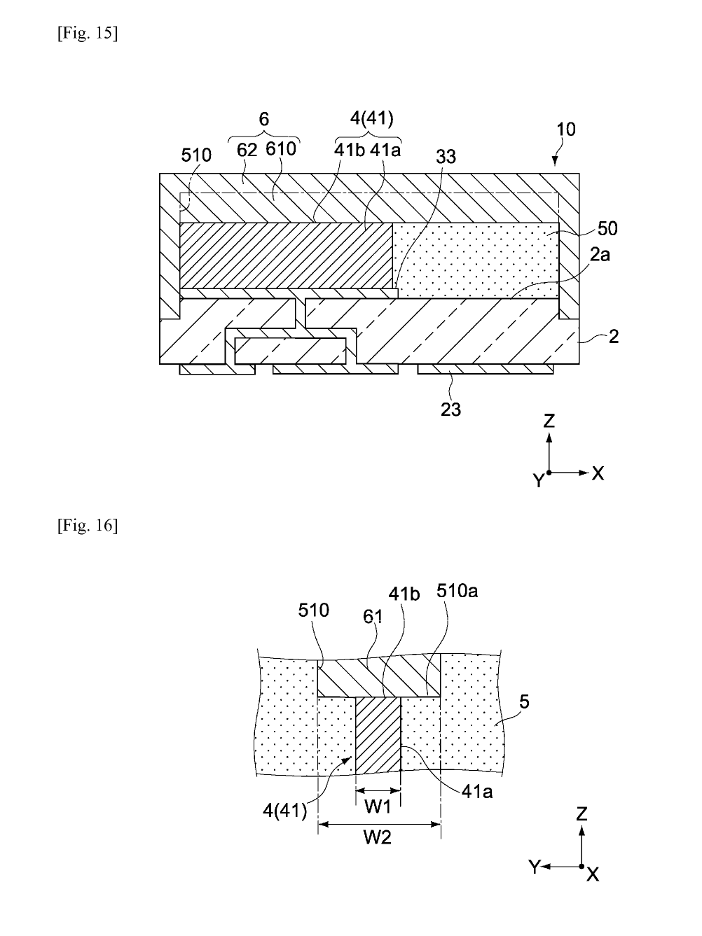

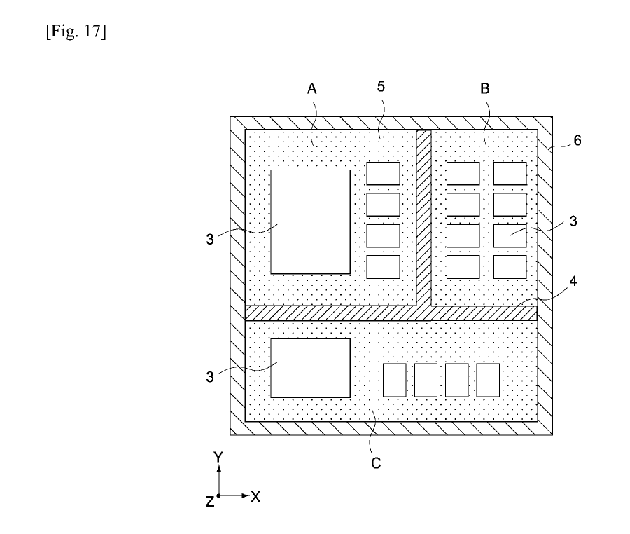

These and other features of this invention will now be described with reference to the drawings of preferred embodiments which are intended to illustrate and not to limit the invention. The drawings are greatly simplified for illustrative purposes and are not necessarily to scale.

[FIG. 1] is a schematic perspective view showing the constitution of a circuit module pertaining to the first embodiment of the present invention.

[FIG. 2] is a front view of the circuit module.

[FIG. 3] is a plan view of the circuit module.

[FIG. 4] is a section view of FIG. 2 cut along line [A]-[A].

[FIG. 5] consists of (A) which is a section view of FIG. 3 cut along line [B]-[B], and (B) and (C) which are enlarged views showing key parts of (A).

[FIG. 6] is a section view of FIG. 3 cut along line [C]-[C].

[FIG. 7] is a top view showing the constitution of a board assembly used for manufacturing the circuit module.

[FIG. 8] is a drawing explaining how the circuit module is manufactured, where (A) is a top view explaining the component installation step, while (B) is a section view showing key parts.

[FIG. 9] is a drawing explaining how the circuit module is manufactured, where (A) is a top view explaining the sealing layer forming step, while (B) is a section view showing key parts.

[FIG. 10] is a drawing explaining how the circuit module is manufactured, where (A) is a top view explaining the half-cut step, while (B) is a section view showing key parts.

[FIG. 11] is a drawing explaining how the circuit module is manufactured, where (A) is a top view explaining the groove forming step, while (B) is a section view showing key parts.

[FIG. 12] is a drawing explaining how the circuit module is manufactured, where (A) is a top view explaining the cover layer forming step, while (B) is a section view showing key parts.

[FIG. 13] is a drawing explaining how the circuit module is manufactured, where (A) is a top view explaining the cutting step, while (B) is a section view showing key parts.

[FIG. 14] is a drawing explaining how a circuit module pertaining to the second embodiment of the present invention is manufactured, where (A) is a top view explaining the groove forming step, while (B) is a section view showing key parts.

[FIG. 15] is a section view of a part of the shield member in FIG. 14 as viewed in the Y-axis direction.

[FIG. 16] is an enlarged section view of key parts, illustrating an example of variation of the groove in an embodiment of the present invention.

[FIG. 17] is a section view illustrating an example of variation of the constitution in FIG. 4.

### DESCRIPTION OF THE SYMBOLS

1 - - - Circuit module

2 - - - Board

3, 31, 32 - - - Electronic component

4 - - - Shield member

5 - - - Sealing layer

6 - - - Cover layer

21 - - - First area

22 - - - Second area

41 - - - First shield plate

42 - - - Second shield plate

41a, 42a - - - Side face

41b, 42b - - - Upper end face

51, 510 - - - Groove

51a, 510a - - - Bottom face

52 - - - Concave part

61, 610 - - - First cover layer

62 - - - Second cover layer

### DETAILED DESCRIPTION OF EMBODIMENTS

The circuit module pertaining to an embodiment of the present invention has a board, multiple electronic components, shield member, sealing layer, and cover layer.

The board has a mounting surface that includes a first area and second area.

The multiple electronic components are mounted in the first area and second area, respectively.

The shield member is constituted by a first conductor and is placed between the first area and second area of the mounting surface.

The sealing layer has on its top surface a groove having a bottom face including an upper end face of the shield member, or specifically a groove that exposes the upper end face of the shield member, is formed on the mounting surface, and is constituted by an insulator that covers the multiple electronic components.

The cover layer has a first cover part that fills the groove as well as a second cover part that covers the first cover part and sealing layer, and is constituted by a second conductor.

The shield member and cover layer are connected inside the groove formed in the sealing layer, to function as an interior shield of the circuit module. This constitution also enhances the durability against thermal stress or other stress applied to the top face of the sealing layer in parallel direction, which improves the reliability of connection between the shield member and first cover part. As a result, stable shield function can be ensured.

The first conductor may be constituted by metal material, while the second conductor may be constituted by conductive resin material. This way, mechanical strength of the shield member can be ensured and the cover layer can be formed in a stable manner on the surface of the sealing layer that includes the groove.

When the height of the highest electronic component among the multiple electronic components as measured from the mounting surface is given as a first height, the shield member may be formed at a second height from the mounting surface which is lower than the first height.

This way, the thickness of the circuit module is no longer limited by the height of the shield member, which makes it possible to easily achieve thickness reduction of the circuit module.

The shield member may have a first shield plate and a second shield plate that intersects with the first shield plate.

This way, the shield member can be self-supported on the mounting surface without requiring any separate constitution to support the shield member, which contributes to size reduction of the circuit module and simplification of the equipment constitution.

The shield member may include an upper end face connecting to the first cover part inside the groove in the sealing layer, and a side face provided at a part continuing from this end face and connecting to the first cover part. The end face may be placed on the same plane as the bottom face of the groove, or it may be placed in a manner projecting from the bottom face of the groove toward the interior of the groove.

The bottom face of the groove may be formed with an area greater than the end face of the shield member.

This way, the entire area of the end face can be connected to the first cover part to enhance the reliability of connection between the shield member and cover layer.

The groove may further include a deep concave part placed adjacent to and extending from the end face of the shield member and, such as one having a wedge-shaped cross-section, so as to connect the first cover part on both the first area side and second area side.

The concave part allows the first cover part to contact not only the end face of the shield member, but also a part of the side face. This increases the joining area between the shield member and the first cover part, which in turn further enhances the reliability of connection between them.

The manufacturing method of a circuit module pertaining to an embodiment of the present invention includes a step to mount multiple electronic components in a first area and second area on a mounting surface.

A shield member constituted by a first conductor is placed between the first area and second area on the board.

A sealing layer covering the multiple electronic components and shield member and constituted by an insulator is formed on the board. A part of the sealing layer is removed from the shield member to form a groove to expose the shield member.

A cover layer constituted by a second conductor is formed on the sealing layer, to form a first cover part that fills the groove, as well as a second cover part that covers the first cover layer and sealing layer.

In the manufacturing process, the sealing layer is removed only partially to form a groove to expose the shield member from the sealing layer, in order to ensure connection between the shield member and cover layer. This enhances the reliability of connection between the shield member and cover layer and makes it possible to manufacture a circuit module whose shield member is lower than the electronic components and which is therefore suitable for thickness reduction.

In the groove forming step, a concave part adjacent to the side face may be formed in the bottom face of the groove. This way, the reliability of connection between the shield member and cover layer can be enhanced further. Such concave part can be formed simultaneously with the groove by forming the groove by means of laser processing, for example.

Embodiments of the present invention are explained below by referring to the drawings.

### First Embodiment

### [Circuit Module]

FIGS. 1 to 3 are schematic views showing the exterior of a circuit module pertaining to an embodiment of the present invention, where FIG. 1 is a perspective view, FIG. 2 is a front view, and FIG. 3 is a plan view. On the other hand, FIG. 4 is a section view of FIG. 2 cut along line [A]-[A], FIG. 5(A) is a section view cut along line [B]-[B], and FIGS. 5(B) and (C) are enlarged views showing key parts of FIG. 5(A). FIG. 6 is a section view of FIG. 3 cut along line [C]-[C].

In each drawing, the X, Y and Z axes represent three axis directions that are mutually orthogonal, where the Z-axis direction corresponds to the thickness direction of the circuit module. To facilitate understanding, the constitution of each part is exaggerated.

The circuit module 1 pertaining to this embodiment has a board 2, multiple electronic components 3, a shield member 4, sealing layer 5, and cover layer 6.

The circuit module 1 is constituted to have an overall shape of roughly a rectangular solid. Its size is not limited in any way and the lengths in the X-axis direction and Y-axis direction may be in a range of 10 to 50 mm, for example, where, in this embodiment, the module is roughly a square of approx. 35 mm per side. The thickness is not limited in any way, either, and may be in a range of 1 to 3 mm, for example, where the thickness is approx. 2 mm in this embodiment.

The circuit module 1 has its multiple electronic components 3 placed on the board 2, with the sealing layer 5 and cover layer 6 formed in a manner covering the foregoing. The constitution of each part of the circuit module 1 is explained below.

### [Board]

The board 2 is constituted by, for example, a glass epoxy multi-layer wiring board of approx. 0.4 mm in thickness, for example, having a mounting surface 2a which is constituted as roughly a square having the same dimensions as the circuit module 1 as a whole, for example. The material constituting the insulation layer on the board 2 is not limited to glass epoxy as mentioned above, and it is possible to adopt insulating ceramic material, etc., for example.

Wiring layers of the board 2 are typically constituted by copper foils and placed on the front side and back side and in the inner layer of the board 2. The wiring layers are patterned in specified shapes, respectively, to constitute a top-layer wiring part 23a, bottom-layer wiring part 23b and inner-layer wiring part 23c, respectively. The top-layer wiring part 23a includes a land in which an electronic component 3 is to be mounted, while the bottom-layer wiring part 23b includes an external connection terminal to be connected to a control board (not illustrated) in the electronic equipment in which the circuit module 1 is to be mounted. The wiring parts of the respective layers are connected electrically by via conductors 23v, respectively.

The wiring layers also include a GND terminal 24 to be connected to the ground (GND) potential. The GND terminal 24 is placed adjacent to a stepped part 2b formed along the periphery of the top face of the board 2, and connected to the interior surface of the cover layer 6 placed at the stepped part 2b. The GND terminal 24 may be formed as part of the top-layer wiring part 23a, or it may be formed as part of the inner-layer wiring part 23c. The GND terminal 24 is connected to the ground wiring of the control board via the bottom-layer wiring part 23b.

The mounting surface 2a is divided by the shield member 4 into multiple areas that, in this embodiment, include a first area 21 and second area 22 in which specified electronic components 31, 32 are placed, respectively. The first area 21 constitutes a rectangular area that includes one apex (corner) of the mounting surface 2a, for example. The second area 22 constitutes the area over the mounting surface 2a excluding the first area 21.

### [Electronic Components]

The multiple electronic components 3 are mounted in the first area and second area, 21, 22 on the mounting surface 2a, respectively. Typically the multiple electronic components 3 include various components such as integrated circuits (ICs), capacitors, inductors, resistors, quartz oscillators, duplexers, filters, and power amplifiers.

Some of these components emit electromagnetic waves to their surroundings while operating, while others are susceptible to the influence of such electromagnetic waves. Typically these components are mounted in different areas divided by the shield member 4, respectively. In the following, one or multiple electronic components 3 mounted in the first area 21 are also referred to as “electronic components 31,” while one or multiple electronic components 3 mounted in the second area 22 are also referred to as “electronic components 32.”

The multiple electronic components 3 are typically mounted on the mounting surface 2a by means of solder, adhesive, bonding wire, etc.

### [Shield Member]

The shield member 4 functions as part of an interior shield that suppresses electrical interference between the electronic components 31, 32, and is placed between the first area 21 and second area 22 on the mounting surface 2a.

The shield member 4 is constituted by metal material (first conductor) in this embodiment. For the metal material, copper (Cu), nickel (Ni), Cu/Ni/Zn alloy (nickel silver), etc., can be adopted, for example, but needless to say the metal material is not limited to the foregoing in any way. The constituent material of the shield member 4 is not limited to metal material, and hardened conductive resin, carbon composite or other conductor, or microwave absorber including soft magnetic material, may be adopted, for example. For the constituent material of the shield member 4, one that can mechanically and electrically connect to the top-layer wiring part 23a on the board is more preferable.

In this embodiment, the shield member 4 has a first shield plate 41 and second shield plate 42. As shown in FIG. 4, the first shield plate 41 and second shield plate 42 intersect (they are orthogonal in this example), where the first shield plate 41 is placed in parallel with the X-axis direction, while the second shield plate 42 is placed in parallel with the Y-axis direction. One end of the first shield plate 41 faces the left end of the board 2 in FIG. 4, while one end of the second shield plate 42 faces the top end of the board 2 in FIG. 4, and the other ends of the shield plates 41, 42 are connected to each other.

In this embodiment, the shield member 4 is constituted by a press-formed metal plate which is bent by roughly 90° at the center into an L-shape, and the first shield plate 41 and second shield plate 42 are integrally formed as one piece. Alternatively, the shield member 4 may be constituted in such a way that independently constituted first shield plate 41 and second shield plate 42 are joined using conductive adhesive, etc. Furthermore, the shield member 4 may be formed in such a way that its end-face side has a T-shaped cross-section, or that its board side has a T-shaped cross-section. For the shape of the shield member 4, any shape may be used as necessary.

The constitution where the first shield plate 41 and second shield plate 42 intersect allows the shield member 4 to be self-supported on the mounting surface 2a. This eliminates the need for any separate constitution, etc., to support the shield member 4 on the mounting surface 2a and thereby simplifies the equipment constitution and manufacturing process.

The first shield plate 41 has two side faces 41 a that are facing each other in the Y-axis direction, as well as an upper end face 41b that continues to the two side faces 41a and constitutes the top face. FIG. 5(B) is a section view of the first shield plate 41 as viewed in the X-axis direction. As shown in FIGS. 5(A) and (B), the first shield plate 41 has a height T2 and width W1. A height T2 represents the height of the shield plate 41 as viewed from the mounting surface 2a in the Z-axis direction and is set lower than the height T1 of the highest electronic component among the multiple electronic components 3 as measured from the mounting surface 2a. The width W1 represents the width of the shield plate 41 in the Y-axis direction.

FIG. 5(C) is a section view of the second shield plate 42 as viewed in the Y-axis direction. As shown in FIGS. 5(A) and (C), the second shield plate 42 has two side faces 42a that are facing each other in the X-axis direction, as well as an upper end face 42b that continues to the two side faces 42a and constitutes the top face. The second shield plate 42 has the same height and width as the first shield plate 41.

The bottom face of the shield member 4 is fixed on the mounting surface 2a. The shield member 4 may be fixed to the surface of the insulation layer on the mounting surface 2a, or it may be fixed on a part of the top-layer wiring part 23a. In this embodiment, the shield member 4 is joined onto a terminal 23a1 that constitutes a part of the top-layer wiring part 23a. The height T2 of the shield member 4 includes the width of the terminal 23a1 and corresponds to the mounting height from the mounting surface 2a. For the joining material, solder is used, for example. The terminal 23a1 may be connected to the ground potential, or it may be a dummy terminal.

### [Sealing Layer]

The sealing layer 5 constitutes an insulation layer which is formed on the mounting surface 2a in a manner covering the multiple electronic components 31, 32. The sealing layer 5 is formed adjacent to the two side faces 41a, 42a of the shield member 4 and is divided into the first area 21 and second area 22 by the shield member 4. The sealing layer 5 is constituted by insulator material, and silica or alumina-spiked epoxy resin or other insulation resin is adopted in this embodiment, for example.

The sealing layer 5 has on its top surface a groove 51 having a bottom face 51a including an upper end face of the shield member 4. The groove 51 is formed directly above end faces 41b, 42b of the shield member 4, to a specified depth as measured in the Z-axis direction from the top face of the sealing layer 5. The bottom face 51 a of the groove 51 may be formed to a depth that would make it flush with the end faces 41b, 42b of the shield member 4, or it may be formed to a depth that would allow the end faces 41b, 42b to project.

In this embodiment, the groove 51 is formed with a width W2 greater than the width of the end faces 41b, 42b of the shield member 4, as shown in FIGS. 5(B) and (C). In other words, the bottom face 51a has a greater area than the end faces 41b, 42b and is formed to a size that includes the end faces 41b, 42b. The cross-section shape of the groove 51 as viewed in the X-axis direction is not limited to the rectangle shown, but it may be a trapezoid, parallelogram, semi-ellipsoid, etc., according to the forming method of the groove 51.

The groove 51 further includes a concave part 52 which is formed in the bottom face 51a adjacent to the side faces 41a, 42a. The concave part 52 is formed in a part of the bottom face 51a and has a tapered surface so that its depth from the bottom face 51a increases toward the side faces 41a, 42a. The depth of the concave part 52 is not limited in any way. With the formation of the concave part 52, not only the end faces 42a, 42b of the shield plates 41, 42, but also parts of the side faces 41a, 42a, are placed in the groove 51.

The forming method of the groove 51 is not limited in any way, and it is formed by laser processing or by machining using a dicer, router, etc. As mentioned later, in this embodiment the groove 51 is formed using laser processing technology, and the concave part 52 is formed simultaneously with the groove 51.

### [Cover Layer]

The cover layer 6 is formed in a manner covering the entire circuit module 1 excluding parts of the board 2. The cover layer 6 is constituted by conductive resin material (second conductor) in this embodiment, and more specifically epoxy resin to which Ag, Cu or other conductive grains have been added is adopted, for example.

The cover layer 6 has a first cover part 61 and second cover part 62. The first cover part 61 fills the groove 51 and is joined to the end faces 41b, 42b of the shield member 4 placed on the bottom face 51a of the groove 51. This way, the first cover part 61 and shield member 4 are electrically/mechanically connected and, together with the shield plates 41, 42, the first cover part 61 constitutes an interior shield that suppresses the influence of electromagnetic waves between the electronic components 31, 32.

Furthermore, the first cover part 61 also fills the concave part 52 formed in the bottom face 51a of the groove 51 and is thereby joined to the side faces 41a, 42a of the shield member 4, as well. This enhances the joining strength between the first cover part 61 and the shield member 4 due to the anchor effect.

The second cover part 62 is formed in a manner covering the first cover part 61 as well as the surface and side periphery of the sealing layer 5. This way, the second cover part 62 constitutes an exterior shield that suppresses the leakage of electromagnetic waves to the outside or entry of electromagnetic waves from the outside.

In addition, as the second cover part 62 is constituted in a manner covering the stepped part 2b formed at the side face of the board 2, the second cover part 62 is connected to the GND terminal 24. This way, the cover layer 6 and shield member 4 connected to it become connected to the ground potential via the GND terminal 24, to enhance the interior shield effect and exterior shield effect by means of the shield member 4 and cover layer 6.

With the circuit module 1 thus constituted pertaining to this embodiment, the height T2 of the shield member 4 from the mounting surface is lower than the height T1 of the highest electronic component among the multiple electronic components 3 as measured from the mounting surface 2a. This way, the thickness of the circuit module 1 is no longer limited by the height of the shield member, which facilitates thickness reduction of the circuit module.

In addition, as the shield member 4 and cover layer 6 are connected to each other in the groove 51 formed in the sealing layer 5, the durability against thermal stress or other stress applied to the top face of the sealing layer 5 in parallel direction is enhanced, which in turn improves the reliability of connection between the shield member 4 and first cover part 61.

Furthermore, as the first cover part 61 of the cover layer 6 is constituted as part of the interior shield, the shield member 4 can be made lower. As a result, the distance over which the shield member 4 contacts the sealing layer 5 in its height direction becomes shorter and this reduces the possibility of separation and cracking due to a difference in the coefficient of linear thermal expansion between the shield member 4 and sealing layer 5. This in turn suppresses corrosion, etc., of components due to water vapor (humidity) entering from the outside and ensures stable characteristics of the circuit module 1 over a long period.

### [Manufacturing Method of Circuit Module]

Next, the manufacturing method of the circuit module 1 is explained.

FIGS. 7 to 13 are drawings explaining how the circuit module 1 is manufactured. In FIGS. 8 to 13, (A) is a top view, while (B) is a section view of key parts as viewed in the X-axis direction. The manufacturing method of the circuit module pertaining to this embodiment has a board assembly preparation step, electronic component mounting step, shield member placement step, sealing layer forming step, half-cut step, groove forming step, cover layer forming step, and cutting step. Each step is explained below.

### (Board Assembly Preparation Step)

FIG. 7 is a top view that schematically illustrates the constitution of a board assembly 25. The board assembly 25 is constituted by a large board on which multiple boards 2 are attached. FIG. 7 shows the separation lines L that divide the multiple boards 2. These separation lines L may be virtual lines or physical lines that are printed or otherwise drawn on the board assembly 25.

The board assembly 25 has completed the steps explained later until forming of the cover layer 6, and when cut (fully) along the separation lines L in the last cutting step, one board assembly 25 produces multiple circuit modules 1. In addition, although not illustrated, specified wiring patterns (23a, 23a1, 23b, 23c, 23v, 24, etc.) are formed inside the board assembly 25 in each area constituting a board 2.

Four boards 2 are cut out from one board assembly 25 in the illustrated example, but the number of boards 2 to be cut out is not limited in any way. For example, if a roughly square board of approx. 150 mm×150 mm in size is used as the board assembly 25, a total of 16 boards 2, each of approx. 35 mm×35 mm in size, are arranged by four each in the X-axis direction and in the Y-axis direction. Typically, a rectangular board of approx. 100 to 200 mm per side is adopted for the board assembly 25.

### (Electronic Component Mounting Step)

FIGS. 8(A) and (B) are drawings that explain the electronic component mounting step and shield member placement step, showing how electronic components 3 (31, 32) and shield member 4 (41, 42) are placed on the board assembly 25.

In this step, multiple electronic components 3 (31, 32) are mounted in the first area 21 and second area 22 on the mounting surface 2a, respectively. For the component 3 mounting method, the reflow method is adopted, for example. To be specific, solder paste is applied to specified lands on the mounting surface 2a by means of screen printing, etc., followed by installation of multiple electronic components 3 on the specified lands via solder paste. Thereafter, the board assembly 25 on which the electronic components 3 have been installed are put in a reflow oven to reflow the solder paste, in order to cause the electronic components 3 to be electrically/mechanically joined onto the mounting surface 2a of the board 2.

### (Shield Member Placement Step)

In this step, explained by again referring to FIG. 8, a shield member 4 is placed along the boundary of the first area 21 and second area 22 on the board 2. The shield member 4 pertaining to this embodiment has a first shield plate 41 and second shield plate 42 that intersect at approx. 90° and thus can be self-supported on the mounting surface 2a without requiring any separate constitution to support the shield member 4 (41, 42). This step can be implemented by the reflow method at the same time as the electronic component mounting step mentioned above, and the shield member 4 is soldered onto a terminal 23a1. At this time, the shield member 4 is mounted on the mounting surface 2a at a height T2 lower than the height T1 of the highest component among the multiple electronic components 3 (FIG. 8(B)).

### (Sealing Layer Forming Step)

FIGS. 9(A) and (B) are drawings that explain the sealing layer forming step, showing how a sealing layer 5 is formed on the mounting surface 2a.

The sealing layer 5 is formed on the mounting surface 2a of the board 2 in a manner covering the multiple electronic components 3 and shield member 4. The sealing layer 5 is formed at a thickness that makes it slightly higher than the height T1 of the electronic component 31, and this way all electronic components 3 including the shield member 4 are covered by the sealing layer 5.

The forming method of the sealing layer 5 is not limited in any way, and the molding method using a mold or potting method not using a mold can be applied, for example. It is also possible to apply sealing resin material in liquid or paste form on the mounting surface 2a by the spin-coating method or screen printing method and then heat-treat the surface.

### (Half-Cut Step)

FIGS. 10(A) and (B) are drawings that explain the half-cut step. In this step, a dicer is used to form cut grooves C, along the separation lines L, to a depth reaching from the top face of the sealing layer 5 into the board 2. The cut groove C forms a stepped part 2b of the board 2. The depth of the cut groove C is not limited in any way, but the groove is formed at a depth that allows the GND terminal 24 on the board 2 to be divided.

### (Groove Forming Step)

FIGS. 11(A) and (B) are drawings that explain the groove forming step. The groove 51 is formed by removing a part of the sealing layer 5 directly above the shield member 4 so that the shield member 4 is exposed. To be specific, the groove 51 is formed from above the sealing layer 5, with a width W2 wider than the width W1 of the end faces 41b, 42b of the shield member 4, along the end faces 41b, 42b (refer to FIG. 3(B)).

In this embodiment, the groove 51 is formed using the laser processing method. The type of laser is not limited in any way, and CO₂ laser, UV solid laser, semiconductor laser, excimer laser, etc., can be adopted, for example, and appropriate oscillation conditions that allow the sealing layer 5 to be removed where it is covering the end faces 41b, 42b of the shield member 4 are applied.

In this step, a laser beam is scanned over the sealing layer 5 along the end faces 41b, 42b of the shield member 4, to partially melt and remove the sealing layer 5 where it is irradiated with the laser beam. This way, the sealing layer 5 is partially removed where it is covering the end faces 41b, 42b of the shield member 4, to form a groove 51 having a bottom face 51a of roughly the same height as the end faces 41b, 42b.

Additionally, when the groove 51 is formed in the aforementioned method, a concave part 52 shown in FIGS. 5(B) and (C) is formed simultaneously in the bottom face 51a. The concave part 52 is formed as the constituent resin of the sealing layer 5 melts locally where it is contacting the side faces 41a, 42a of the shield member 4 being heated by the irradiated laser beam. The depth of the concave part 52 can be controlled by the output of the irradiated laser beam, the scan speed, and so on, for example. The concave part 52 may be formed as a deep groove having a width W2, by controlling the output of the irradiated laser beam or the scan speed, so that the end faces 41b, 42b of the shield member 4 of the concave part 52 become exposed.

### (Cover Layer Forming Step)

FIGS. 12(A) and (B) are drawings that explain the cover layer forming step. The cover layer 6 is formed on the sealing layer 5. This way, a first cover part 61 that fills the groove 51, and a second cover part 62 that covers the first cover part 61 and sealing layer 5, are formed.

The cover layer forming step is not limited in any way, and the molding method using a mold or potting method not using a mold can be applied, for example. It is also possible to apply sealing resin material in liquid or paste form on the mounting surface 2a by the spin-coating method or screen printing method and then heat-treat the surface.

The first cover part 61 fills the groove 51. As a result, it is joined to the end faces 41b, 42b of the shield member 4 exposed on the bottom face 51a of the groove 51. In this embodiment, the first cover part 61 is also joined with parts of the end faces 41a, 42a of the shield member 4 via the concave part 52, and this enhances the joining strength between the shield member 4 and first cover part 61 in the groove 51. In addition, the fact that the first cover part 61 and second cover part 62 are constituted by the same material ensures the specified joining strength between the first cover part 61 and second cover part 62.

The conductive resin constituting the second cover part 62 also fills the cut groove C formed in the sealing layer 5 and thus is joined to the GND terminal 24 on the board 2 facing the cut groove C. As a result, the cover layer 6 and GND terminal 24 are connected to each other electrically/mechanically.

### (Cutting Step)

FIGS. 13(A) and (B) are drawings that explain the cutting step. In this step, the board assembly 25 is fully cut along the separation lines L into individual multiple circuit modules 1. For this separation, a dicer, etc., can be used, for example. In this embodiment, the cover layer 6 also fills the cut grooves C, which means that, when separated along the separation line L, the board 2 and cover layer 6 have identical cut faces. This way, a circuit module 1 on which the cover layer 6 is formed in a manner covering the surface (top face and side faces) of the sealing layer 5 and parts of the side faces of the board 2 is produced.

The circuit module 1 is manufactured through the above steps. Under the manufacturing method of the circuit module pertaining to this embodiment, a step is provided to form a groove 51 by partially removing the sealing layer 5 in order to ensure electrical continuity of the shield member 4 and cover layer 6. This step is simpler and more cost-effective than when the entire top face of the sealing layer 5 is ground or otherwise removed.

Also, the groove 51 is formed only directly above the shield member 4, which improves the ease of filling of the conductive resin, etc., constituting the cover layer 6. This enhances the electrical/mechanical reliability of connection between the shield member 4 and cover layer 6. Also, the groove 51 is filled more quickly with the conducive resin and the resin can be filled stably when the width W2 of the groove 51 is relatively small, which contributes to size reduction of the entire circuit module 1.

Furthermore, the manufacturing method of the circuit module 1 pertaining to this embodiment is such that conductive resin is adopted as the material for the cover layer 6 that functions as an exterior shield, and the sealing layer 5 is half-cut along the separation lines L beforehand. This way, the first cover part 61 to fill the groove 51 can be formed together, in the same step, with the second cover part 62 to cover the side and top faces of the sealing layer 5, which simplifies the manufacturing process.

### Second Embodiment

FIGS. 14 to 16 illustrate the second embodiment of the present invention. This embodiment is explained by focusing on those portions different from the first embodiment, and those portions similar to the constitution and effects of the first embodiment are either not explained or explained in a simple way.

In this embodiment, the step to form the groove to be filled by the first cover part 61 of the cover layer 6 is different from the first embodiment mentioned above. FIG. 14(A) is a top view of the board assembly 25 showing the groove forming step, FIG. 14(B) is a section view of key parts as viewed in the Y-axis direction, FIG. 15 is a section view of key parts of the circuit module after forming of the cover layer as viewed in the Y-axis direction, and FIG. 16 is a section view of key parts showing the shape of the groove.

The circuit module pertaining to this embodiment has a groove 510 formed with a dicer on the top face of the sealing layer 5. The groove 510 is formed not only in the area directly above the shield member 4, but also to the same depth over the entire areas along the extension lines of the end faces 41b, 42b of this member in the lateral direction and vertical direction along the X-axis direction and Y-axis direction of the sealing layer 5, respectively.

The end faces 41b, 42b of the shield member 4 are exposed to the outside via the groove 510. The end faces 41b, 42b of the shield member 4 are placed in the groove 510 flush with the groove's bottom face 510a (the relationship of the end face 41b and bottom face 510a is shown in FIG. 16). In this embodiment, the width W2 of the groove 510 is formed larger than the width W1 of the shield member 4, and the end faces 41b, 42b are placed roughly at the center of the bottom face 510a of the groove 510.

The cover layer 6 has a first cover part 610 that fills the groove 510, as well as a second cover part 620 that covers the first cover part 610 and surface of the sealing layer 5. As shown in FIG. 15, the first cover part 610 is formed to the same depth over the entire areas in the lateral direction and vertical direction along the X-axis direction and Y-axis direction of the sealing layer 5, respectively, corresponding to the area where the groove 510 is formed.

This embodiment also achieves the same effects as those achieved by the first embodiment described above. According to this embodiment, the groove 510 is also formed outside the area where the shield member 4 is placed, and this enhances the adhesion between the cover layer 6 and sealing layer 5. As a result, the joining strength between the first cover part 610 and shield member 4 improves and the specified shield function can be ensured in a stable manner.

Also according to this embodiment, where the groove 510 is formed with a dicer, the same machining equipment used in the half-cut step, cutting step, etc., can be used to reduce the equipment cost.

Additionally, forming the groove 510 with a dicer makes it possible to partially grind and machine the end faces 41b, 42b of the shield member 4 at the same time when the groove 510 is formed. Accordingly, it is possible to form the shield member 4 with a height equivalent to that of the electronic component 3 and adopt a step to machine the shield member 4 to the target mounting height when the groove 510 is machined.

The foregoing explained embodiments of the present invention, but the present invention is not limited to these embodiments in any way and various variations are possible based on the technical concept of the present invention.

For example, the above embodiments explained examples where the mounting surface 2a was divided into two areas 21, 22 using the shield member 4, but the number of divisions of this area is not limited to two, and it can be divided into three areas of A, B and C, or more, as shown in FIG. 17. In this case, the shield member can be formed in a T-shape, cross shape, X-shape, etc. It is also possible to use two or more shield members to divide the mounting surface into multiple areas.

Also in the above embodiments, the constitution was such that the end faces 41b, 42b of the shield member 4 were placed in parts of the bottom face 51a or 510a of the groove 51 or 510, but the width of the groove 51 or 510 can be adjusted so that the entire area of the bottom face 51a or 510a is formed by the end faces 41b, 42b of the shield member 4. In other words, the groove 51 or 510 can be formed narrowly with a depth equivalent to or less than the width of the shield member 4.

Also in the above embodiments, the groove 51 or 510 of the sealing layer 5 was formed over the entire area directly above the shield member 4 (end faces 41b, 42b), but the present invention is not limited to this and the groove can be formed only in a part of this area directly above.

Furthermore in the above embodiments, examples where the board 2 was constituted by a printed wiring board were explained. However, the present invention is not limited to this and the board 2 may be constituted by semiconductor substrates such as silicon substrates, for example. Also, the electronic component 3 may be any of the various types of actuators such as MEMS (micro electro mechanical system).

In the present disclosure where conditions and/or structures are not specified, a skilled artisan in the art can readily provide such conditions and/or structures, in view of the present disclosure, as a matter of routine experimentation. Also, in the present disclosure including the examples described above, any ranges applied in some embodiments may include or exclude the lower and/or upper endpoints, and any values of variables indicated may refer to precise values or approximate values and include equivalents, and may refer to average, median, representative, majority, etc. in some embodiments. Further, in this disclosure, “a” may refer to a species or a genus including multiple species, and “the invention” or “the present invention” may refer to at least one of the embodiments or aspects explicitly, necessarily, or inherently disclosed herein. In this disclosure, any defined meanings do not necessarily exclude ordinary and customary meanings in some embodiments.

The present application claims priority to Japanese Patent Application No. 2012-093662, filed Apr. 17, 2012, the disclosure of which is incorporated herein by reference in its entirety.

It will be understood by those of skill in the art that numerous and various modifications can be made without departing from the spirit of the present invention. Therefore, it should be clearly understood that the forms of the present invention are illustrative only and are not intended to limit the scope of the present invention.

We/I claim:

1. A circuit module, comprising:
a board having a mounting surface that includes a first area and a second area;
multiple electronic components that are mounted in the first area and second area, respectively;
a shield member constituted by a first conductor, and placed between the first area and second area of the mounting surface;
a sealing layer which has on its top surface a groove having a bottom face including an upper end face of the shield member, is formed on the mounting surface, and is constituted by an insulator that covers the multiple electronic components; and
a cover layer which has a first cover part that fills the groove as well as a second cover part that covers the first cover part and sealing layer, and is constituted by a second conductor.

2. A circuit module according to claim 1, wherein
the first conductor is constituted by metal material, and
the second conductor is constituted by conductive resin material.

3. A circuit module according to claim 1, wherein, when a height of the highest electronic component among the multiple electronic components as measured from the mounting surface is given as a first height, the shield member has a second height from the mounting surface which is lower than the first height.

4. A circuit module according to claim 1, wherein the shield member has:
a first shield plate; and
a second shield plate that intersects with the first shield plate.

5. A circuit module according to claim 1, wherein the shield member includes:
the upper end face joined to the first cover part inside the groove; and
a side face continuing from the upper end face and joined to the first cover part.

6. A circuit module according to claim 5, wherein the bottom face of the groove is formed with a greater area than the upper end face of the shield member as viewed from above.

7. A circuit module according to claim 6, wherein the groove further includes a concave part at the bottom face, which concave part is adjacent to and extends from the upper end face of the shield member.

8. A manufacturing method of a circuit module, comprising:
mounting multiple electronic components in a first area and a second area on a mounting surface;
placing a shield member constituted by a first conductor between the first area and second area on a board;
covering the multiple electronic components and shield member and forming a sealing layer constituted by an insulator on the board;
partially removing the sealing layer on the shield member, to form a groove to expose the shield member; and
forming a cover layer constituted by a second conductor on the sealing layer, to form a first cover part that fills the groove as well as a second cover part that covers the first cover part and sealing layer.

9. A manufacturing method of a circuit module according to claim 8, wherein a concave part adjacent to the side face is formed in the bottom face of the groove in the groove forming step.
